(19) United States
(12) Patent Application Publication
(10) Pub. No.: US 2026/0280488 A1
(43) Pub. Date: Sep. 17, 2026

(54) PHASE-ADJUSTMENT OF MULTIPHASE LOCAL OSCILLATOR (LO) SIGNALS FOR A HARMONIC REJECTION MIXER (HRM)

(71) Applicant: QUALCOMM Incorporated, San Diego, CA (US)

(72) Inventors: Asad Ali Nawaz, San Diego, CA (US); Ibrahim Ramez Chamas, Carlsbad, CA (US); Yung-Chung Lo, San Diego, CA (US)

(21) Appl. No.: 19/078,004

(22) Filed: Mar. 12, 2025

(51) Int. Cl. H03D 7/00; H03K 5/00; H03K 5/01; H03K 19/0175

(52) U.S. Cl. CPC H03D 7/18; H03D 2200/0086

(57) ABSTRACT

An apparatus includes a multiphase harmonic rejection mixer (HRM) configured to receive a plurality of multiphase local oscillator (LO) signals. The apparatus further includes delay circuitry coupled to the multiphase HRM. The delay circuitry is configured to phase-adjust at least a first LO signal of the plurality of multiphase LO signals relative to a second LO signal of the plurality of multiphase LO signals.

### TECHNICAL FIELD

Aspects of the present disclosure relate generally to wireless communication systems, and more particularly, to radio frequency (RF) processing circuitry for wireless communication systems.

### INTRODUCTION

Wireless communication networks are widely deployed to provide various communication services such as voice, video, packet data, messaging, broadcast, and the like. These wireless networks may be multiple-access networks capable of supporting multiple users by sharing the available network resources.

A wireless communication network may include several components. These components may include wireless communication devices, such as base stations (or node Bs) that may support communication for a number of user equipments (UEs). A UE may communicate with a base station via downlink and uplink. The downlink (or forward link) refers to the communication link from the base station to the UE, and the uplink (or reverse link) refers to the communication link from the UE to the base station.

A base station may transmit data and control information on a downlink to a UE or may receive data and control information on an uplink from the UE. On the downlink, a transmission from the base station may encounter interference due to transmissions from neighbor base stations or from other wireless radio frequency (RF) transmitters. On the uplink, a transmission from the UE may encounter interference from uplink transmissions of other UEs communicating with the neighbor base stations or from other wireless RF transmitters. This interference may degrade performance on both the downlink and uplink.

As the demand for mobile broadband access continues to increase, the possibilities of interference and congested networks grows with more UEs accessing the long-range wireless communication networks and more short-range wireless systems being deployed in communities. Research and development continue to advance wireless technologies not only to meet the growing demand for mobile broadband access, but to advance and enhance the user experience with mobile communications.

Modern wireless communication networks are sophisticated networks that involve operation on multiple frequencies and multiple frequency ranges. RF signals in different frequencies and ranges may use different components or different configurations of components to support a device operating on these wireless communication networks and maintain high signal integrity and high bandwidth across a range of possible network conditions. The duplication of components and number of supported configurations presents challenges in designing RF systems for the UEs and BSs operating on wireless communication networks.

### BRIEF SUMMARY OF SOME EXAMPLES

The systems, methods and devices of this disclosure each have several innovative aspects, no single one of which is solely responsible for the desirable attributes disclosed herein.

In some aspects, an apparatus includes a multiphase harmonic rejection mixer (HRM) configured to receive a plurality of multiphase local oscillator (LO) signals. The apparatus further includes delay circuitry coupled to the multiphase HRM. The delay circuitry is configured to phase-adjust at least a first LO signal of the plurality of multiphase LO signals relative to a second LO signal of the plurality of multiphase LO signals.

In some further aspects, a method includes phase-adjusting at least a first local oscillator (LO) signal of a plurality of multiphase LO signals relative to a second LO signal of the plurality of multiphase LO signals. The method further includes inputting the plurality of multiphase LO signals to a harmonic rejection mixer (HRM).

In some additional aspects, an apparatus includes a harmonic rejection mixer (HRM) and a local oscillator (LO) generation circuit coupled to the HRM. The LO generation circuit includes a phase detector including multiple paths and a first set of switches. The first set of switches includes a respective switch in each path of the multiple paths. The LO generation circuit further includes an amplifier coupled to the phase detector and a second set of switches coupled to at least one of an input of the amplifier or an output of the amplifier. The LO generation circuit further includes a plurality of direct current (DC) level shifters coupled to the amplifier and a plurality of delay lines coupled to the plurality of DC level shifters.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

FIG. 1 is a block diagram illustrating details of an example wireless communication system that supports phase-adjustment of multiphase signals for a harmonic rejection mixer (HRM).

FIG. 2 is a block diagram illustrating examples of base station and a user equipment (UE) that support phase-adjustment of multiphase signals for an HRM.

FIG. 3 is a block diagram illustrating a receiver circuit that supports phase-adjustment of multiphase signals for an HRM.

FIG. 4 is a diagram illustrating an example of configurable HRM control circuitry that supports phase-adjustment of multiphase signals for an HRM.

FIG. 5 is a diagram illustrating an example of a first configurable state of the configurable HRM control circuitry of FIG. 4.

FIG. 6 is a diagram illustrating an example of a second configurable state of the configurable HRM control circuitry of FIG. 4.

FIG. 7 is a diagram illustrating an example of a third configurable state of the configurable HRM control circuitry of FIG. 4.

FIG. 8 is a diagram illustrating an example of a fourth configurable state of the configurable HRM control circuitry of FIG. 4.

FIG. 9 is a block diagram illustrating an example of a calibration subsystem that supports phase-adjustment of multiphase signals for an HRM.

FIG. 10 is a diagram illustrating an example of a mixer stage that supports phase-adjustment of multiphase signals for an HRM.

FIG. 11 is a flow chart illustrating an example of a method of operation of a device that supports phase-adjustment of multiphase signals for an HRM.

Like reference numbers and designations in the various drawings indicate like elements.

### DETAILED DESCRIPTION

Signals received or transmitted by wireless devices may be subject to harmonic distortion and other unwanted signal components. Examples of such signal components may include a third order local oscillator harmonic (3LO) signal component or a third-order counter-intermodulation (CIM3) signal component. Some wireless devices may use a harmonic rejection mixer (HRM) to reduce such signal components in signals. An HRM may use multiphase local oscillator (LO) signals to cancel or reduce particular signal components from a signal. Such multiphase LO signals that have a specific phase relationship with one another, such as a 45 degree phase relationship.

In some devices, a phase error may occur in which the multiphase LO signals are out of phase with one another. As an illustrative example, a phase error may cause multiphase LO signals to be 44 degrees out of phase or 48 degrees out of phase instead of 45 degrees out of phase. Such a phase error may be caused by, for example, process variations associated with a fabrication process of an integrated circuit.

Some techniques for addressing such a phase mismatch may include increasing the size of transistors of an HRM. By increasing the size of the transistors, an effect of the phase mismatch may be reduced (or “hidden”). The increased size of the transistors may increase the size of an integrated circuit and may also increase power consumption.

In some aspects, a device may include HRM control circuitry that adjusts (e.g., calibrates) a harmonic rejection ratio (HRR) of an HRM by enabling individual phase-adjustment of at least some multiphase local oscillator (LO) signals provided to an HRM. For example, portions of a phase detector may be selectively activated and deactivated to enable detection of a phase error associated with a first LO signal of the multiphase LO signals relative to a second LO signal of the multiphase LO signals. In response to the phase error, delay circuitry associated with the first LO signal may be adjusted (e.g., by changing a bias signal of a level shifter that is coupled to a delay line) in order to reduce the phase error. As referred to herein, phase-adjustment may include calibration operations performed during manufacturing or production of a device as well as during other stages, such as during end user operation (e.g., a mission mode) associated with the device.

After determining settings of the delay circuitry (e.g., bias signals provided to level shifters of the delay circuitry) for at least some of the multiphase LO signals, the settings may be stored to a memory. Upon powerup of the device, the delay circuitry may be operated in accordance with the settings (e.g., by providing the bias signals to the level shifters such that phase errors of the multiphase LO signals are canceled or reduced).

One or more features described herein may improve performance of a wireless device (such as a wireless transmitter, a wireless receiver, or both) while also reducing cost, size, and power consumption of the wireless device. For example, in some implementations, LO signals provided to an HRM may be phase adjusted using relatively simple direct current (DC) signals provided to DC level shifters and without increasing size of transistors of the HRM. As a result, device cost, size, and power consumption may be reduced as compared to some other conventional devices, such as devices that increase the size of transistors of an HRM to reduce (or “hide”) effects of a phase mismatch.

In some implementations, one or more features described herein may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5^{th} Generation (5G) or new radio (NR) networks (sometimes referred to as “5G NR” networks, systems, or devices), as well as other communications networks. As described herein, the terms “networks” and “systems” may be used interchangeably.

A CDMA network, for example, may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards.

A TDMA network may, for example implement a radio technology such as Global System for Mobile Communication (GSM). The 3rd Generation Partnership Project (3GPP) defines standards for the GSM EDGE (enhanced data rates for GSM evolution) radio access network (RAN), also denoted as GERAN. GERAN is the radio component of GSM/EDGE, together with the network that joins the base stations (for example, the Ater and Abis interfaces) and the base station controllers (A interfaces, etc.). The radio access network represents a component of a GSM network, through which phone calls and packet data are routed from and to the public switched telephone network (PSTN) and Internet to and from subscriber handsets, also known as user terminals or user equipments (UEs). A mobile phone operator's network may comprise one or more GERANs, which may be coupled with UTRANs in the case of a UMTS/GSM network. Additionally, an operator network may also include one or more LTE networks, or one or more other networks. The various different network types may use different radio access technologies (RATs) and RANs.

An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long-term evolution (LTE) is a release of UMTS that uses E-UTRA. UTRA, E-UTRA, GSM, UMTS and LTE are described in documents provided from an organization named “3rd Generation Partnership Project” (3GPP), and cdma2000 is described in documents from an organization named “3rd Generation Partnership Project 2” (3GPP2). These various radio technologies and standards are known or are being developed. For example, the 3GPP is a collaboration between groups of telecommunications associations that aims to define a globally applicable third generation (3G) mobile phone specification. 3GPP LTE is a 3GPP project which was aimed at improving UMTS mobile phone standard. The 3GPP may define specifications for the next generation of mobile networks, mobile systems, and mobile devices. The present disclosure may describe certain aspects with reference to LTE, 4G, or 5G NR technologies; however, the description is not intended to be limited to a specific technology or application, and one or more aspects described with reference to one technology may be understood to be applicable to another technology. Additionally, one or more aspects of the present disclosure may be related to shared access to wireless spectrum between networks using different radio access technologies or radio air interfaces.

5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (e.g., ~1 M nodes/km²), ultra-low complexity (e.g., ~10 s of bits/sec), ultra-low energy (e.g., ~10+ years of battery life), and deep coverage with the capability to reach challenging locations; (2) including mission-critical control with strong security to safeguard sensitive personal, financial, or classified information, ultra-high reliability (e.g., ~99.9999% reliability), ultra-low latency (e.g., ~1 millisecond (ms)), and users with wide ranges of mobility or lack thereof; and (3) with enhanced mobile broadband including extreme high capacity (e.g., ~10 Tbps/km²), extreme data rates (e.g., multi-Gbps rate, 100+ Mbps user experienced rates), and deep awareness with advanced discovery and optimizations.

Devices, networks, and systems may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHz-7.125 GHz) and FR2 (24.25 GHz-52.6 GHz). The frequencies between FR1 and FR2 are often referred to as mid-band frequencies. Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” (mmWave) band in documents and articles, despite being different from the extremely high frequency (EHF) band (30 GHz-300 GHz) which is identified by the International Telecommunications Union (ITU) as a “mmWave” band.

With the above aspects in mind, unless specifically stated otherwise, it should be understood that the term “sub-6 GHz” or the like if used herein may broadly represent frequencies that may be less than 6 GHz, may be within FR1, or may include mid-band frequencies. Further, unless specifically stated otherwise, it should be understood that the term “mmWave” or the like if used herein may broadly represent frequencies that may include mid-band frequencies, may be within FR2, or may be within the EHF band.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) design or frequency division duplex (FDD) design; and advanced wireless technologies, such as massive multiple input, multiple output (MIMO), robust mmWave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHz FDD or TDD implementations, subcarrier spacing may occur with 15 kHz, for example over 1, 5, 10, 20 MHz, and the like bandwidth. For other various outdoor and small cell coverage deployments of TDD greater than 3 GHz, subcarrier spacing may occur with 30 kHz over 80/100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

For clarity, certain aspects of the apparatus and techniques may be described below with reference to example 5G NR implementations or in a 5G-centric way, and 5G terminology may be used as illustrative examples in portions of the description below; however, the description is not intended to be limited to 5G applications.

Moreover, it should be understood that, in operation, wireless communication networks adapted according to the concepts herein may operate with any combination of licensed or unlicensed spectrum depending on loading and availability. Accordingly, it will be apparent to a person having ordinary skill in the art that the systems, apparatus and methods described herein may be applied to other communications systems and applications than the particular examples provided.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, implementations or uses may come about via integrated chip implementations or other non-module-component based devices (e.g., end-user devices, vehicles, communication devices, computing devices, industrial equipment, retail devices or purchasing devices, medical devices, AI-enabled devices, etc.). While some examples may or may not be specifically directed to use cases or applications, a wide assortment of applicability of described innovations may occur. Implementations may range from chip-level or modular components to non-modular, non-chip-level implementations and further to aggregated, distributed, or original equipment manufacturer (OEM) devices or systems incorporating one or more described aspects. In some practical settings, devices incorporating described aspects and features may also necessarily include additional components and features for implementation and practice of claimed and described aspects. It is intended that innovations described herein may be practiced in a wide variety of implementations, including both large devices or small devices, chip-level components, multi-component systems (e.g., radio frequency (RF)-chain, communication interface, processor), distributed arrangements, end-user devices, etc. of varying sizes, shapes, and constitution.

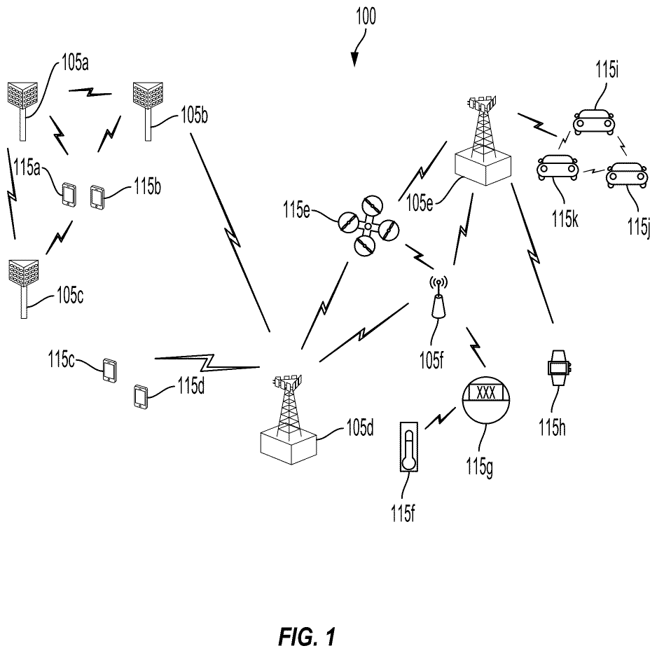

FIG. 1 is a block diagram illustrating details of an example wireless communication system that supports phase-adjustment of multiphase signals for a harmonic rejection mixer (HRM). The wireless communication system may include wireless network 100. Wireless network 100 may, for example, include a 5G wireless network. As appreciated by those skilled in the art, components appearing in FIG. 1 are likely to have related counterparts in other network arrangements including, for example, cellular-style network arrangements and non-cellular-style-network arrangements (e.g., device to device or peer to peer or ad hoc network arrangements, etc.).

Wireless network 100 illustrated in FIG. 1 includes a number of base stations 105 and other network entities. A base station may be a station that communicates with the UEs and may also be referred to as an evolved node B (eNB), a next generation eNB (gNB), an access point, and the like. Each base station 105 may provide communication coverage for a particular geographic area. In 3GPP, the term “cell” may refer to this particular geographic coverage area of a base station or a base station subsystem serving the coverage area, depending on the context in which the term is used. In implementations of wireless network 100 herein, base stations 105 may be associated with a same operator or different operators (e.g., wireless network 100 may include a plurality of operator wireless networks). Additionally, in implementations of wireless network 100 herein, base station 105 may provide wireless communications using one or more of the same frequencies (e.g., one or more frequency bands in licensed spectrum, unlicensed spectrum, or a combination thereof) as a neighboring cell. In some examples, an individual base station 105 or UE 115 may be operated by more than one network operating entity. In some other examples, each base station 105 and UE 115 may be operated by a single network operating entity.

A base station may provide communication coverage for a macro cell or a small cell, such as a pico cell or a femto cell, or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A base station for a macro cell may be referred to as a macro base station. A base station for a small cell may be referred to as a small cell base station, a pico base station, a femto base station or a home base station. In the example shown in FIG. 1, base stations 105d and 105e are regular macro base stations, while base stations 105a-105c are macro base stations enabled with one of 3 dimension (3D), full dimension (FD), or massive MIMO. Base stations 105a-105c take advantage of their higher dimension MIMO capabilities to exploit 3D beamforming in both elevation and azimuth beamforming to increase coverage and capacity. Base station 105f is a small cell base station which may be a home node or portable access point. A base station may support one or multiple (e.g., two, three, four, and the like) cells.

Wireless network 100 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

UEs 115 are dispersed throughout the wireless network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, a gaming device, an augmented reality device, vehicular component, vehicular device, or vehicular module, or some other suitable terminology. Within the present document, a “mobile” apparatus or UE need not necessarily have a capability to move, and may be stationary. Some non-limiting examples of a mobile apparatus, such as may include implementations of one or more of UEs 115, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an IoT or “Internet of everything” (IoE) device such as a vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, gesture tracking device, medical device, a digital audio player (e.g., MP3 player), a camera, a game console, etc.; and digital home or smart home devices such as a home audio, video, and multimedia device, an appliance, a sensor, a vending machine, intelligent lighting, a home security system, a smart meter, etc. In one aspect, a UE may be a device that includes a Universal Integrated Circuit Card (UICC). In another aspect, a UE may be a device that does not include a UICC. In some aspects, UEs that do not include UICCs may also be referred to as IoE devices. UEs 115a-115d of the implementation illustrated in FIG. 1 are examples of mobile smart phone-type devices accessing wireless network 100. A UE may also be a machine specifically configured for connected communication, including machine type communication (MTC), enhanced MTC (eMTC), narrowband IoT (NB-IoT) and the like. UEs 115e-115k illustrated in FIG. 1 are examples of various machines configured for communication that access wireless network 100.

A mobile apparatus, such as UEs 115, may be able to communicate with any type of the base stations, whether macro base stations, pico base stations, femto base stations, relays, and the like. In FIG. 1, a communication link (represented as a lightning bolt) indicates wireless transmissions between a UE and a serving base station, which is a base station designated to serve the UE on the downlink or uplink, or desired transmission between base stations, and backhaul transmissions between base stations. UEs may operate as base stations or other network nodes in some scenarios. Backhaul communication between base stations of wireless network 100 may occur using wired or wireless communication links.

In operation at wireless network 100, base stations 105a-105c serve UEs 115a and 115b using 3D beamforming and coordinated spatial techniques, such as coordinated multipoint (CoMP) or multi-connectivity. Macro base station 105d performs backhaul communications with base stations 105a-105c, as well as small cell, base station 105f. Macro base station 105d also transmits multicast services which are subscribed to and received by UEs 115c and 115d. Such multicast services may include mobile television or stream video, or may include other services for providing community information, such as weather emergencies or alerts, such as Amber alerts or gray alerts.

Wireless network 100 of implementations supports mission critical communications with ultra-reliable and redundant links for mission critical devices, such as UE 115e, which is a drone. Redundant communication links with UE 115e include from macro base stations 105d and 105e, as well as small cell base station 105f. Other machine type devices, such as UE 115f (thermometer), UE 115g (smart meter), and UE 115h (wearable device) may communicate through wireless network 100 either directly with base stations, such as small cell base station 105f, and macro base station 105e, or in multi-hop configurations by communicating with another user device which relays its information to the network, such as UE 115f communicating temperature measurement information to the smart meter, UE 115g, which is then reported to the network through small cell base station 105f. Wireless network 100 may also provide additional network efficiency through dynamic, low-latency TDD communications or low-latency FDD communications, such as in a vehicle-to-vehicle (V2V) mesh network between UEs 115i-115k communicating with macro base station 105e.

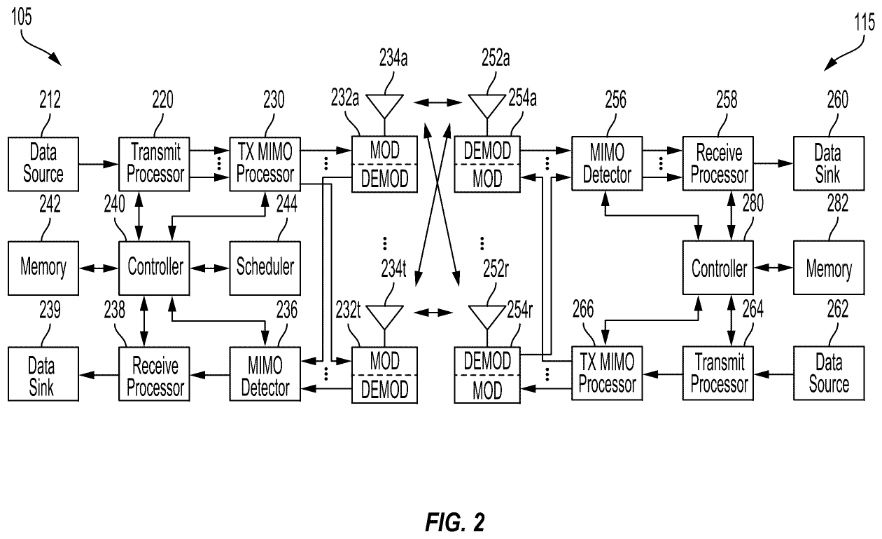

FIG. 2 is a block diagram illustrating examples of base station 105 and UE 115 that support phase-adjustment of multiphase signals for an HRM. Base station 105 and UE 115 may be any of the base stations and one of the UEs in FIG. 1. For a restricted association scenario (as mentioned above), base station 105 may be small cell base station 105f in FIG. 1, and UE 115 may be UE 115c or 115d operating in a service area of base station 105f, which in order to access small cell base station 105f, would be included in a list of accessible UEs for small cell base station 105f. Base station 105 may also be a base station of some other type. As shown in FIG. 2, base station 105 may be equipped with antennas 234a through 234t, and UE 115 may be equipped with antennas 252a through 252r for facilitating wireless communications.

At base station 105, transmit processor 220 may receive data from data source 212 and control information from controller 240, such as a processor. The control information may be for a physical broadcast channel (PBCH), a physical control format indicator channel (PCFICH), a physical hybrid-ARQ (automatic repeat request) indicator channel (PHICH), a physical downlink control channel (PDCCH), an enhanced physical downlink control channel (EPDCCH), an MTC physical downlink control channel (MPDCCH), etc. The data may be for a physical downlink shared channel (PDSCH), etc. Additionally, transmit processor 220 may process (e.g., encode and symbol map) the data and control information to obtain data symbols and control symbols, respectively. Transmit processor 220 may also generate reference symbols, e.g., for the primary synchronization signal (PSS) and secondary synchronization signal (SSS), and cell-specific reference signal. Transmit (TX) MIMO processor 230 may perform spatial processing (e.g., precoding) on the data symbols, the control symbols, or the reference symbols, if applicable, and may provide output symbol streams to modulators (MODs) 232a through 232t. For example, spatial processing performed on the data symbols, the control symbols, or the reference symbols may include precoding. Each modulator 232 may process a respective output symbol stream (e.g., for OFDM, etc.) to obtain an output sample stream. Each modulator 232 may additionally or alternatively process (e.g., convert to analog, amplify, filter, and upconvert) the output sample stream to obtain a downlink signal. Downlink signals from modulators 232a through 232t may be transmitted via antennas 234a through 234t, respectively.

At UE 115, antennas 252a through 252r may receive the downlink signals from base station 105 and may provide received signals to demodulators (DEMODs) 254a through 254r, respectively. Each demodulator 254 may condition (e.g., filter, amplify, downconvert, and digitize) a respective received signal to obtain input samples. Each demodulator 254 may further process the input samples (e.g., for OFDM, etc.) to obtain received symbols. MIMO detector 256 may obtain received symbols from demodulators 254a through 254r, perform MIMO detection on the received symbols if applicable, and provide detected symbols. Receive processor 258 may process (e.g., demodulate, deinterleave, and decode) the detected symbols, provide decoded data for UE 115 to data sink 260, and provide decoded control information to controller 280, such as a processor.

On the uplink, at UE 115, transmit processor 264 may receive and process data (e.g., for a physical uplink shared channel (PUSCH)) from data source 262 and control information (e.g., for a physical uplink control channel (PUCCH)) from controller 280. Additionally, transmit processor 264 may also generate reference symbols for a reference signal. The symbols from transmit processor 264 may be precoded by TX MIMO processor 266 if applicable, further processed by modulators 254a through 254r (e.g., for SC-FDM, etc.), and transmitted to base station 105. At base station 105, the uplink signals from UE 115 may be received by antennas 234, processed by demodulators 232, detected by MIMO detector 236 if applicable, and further processed by receive processor 238 to obtain decoded data and control information sent by UE 115. Receive processor 238 may provide the decoded data to data sink 239 and the decoded control information to controller 240.

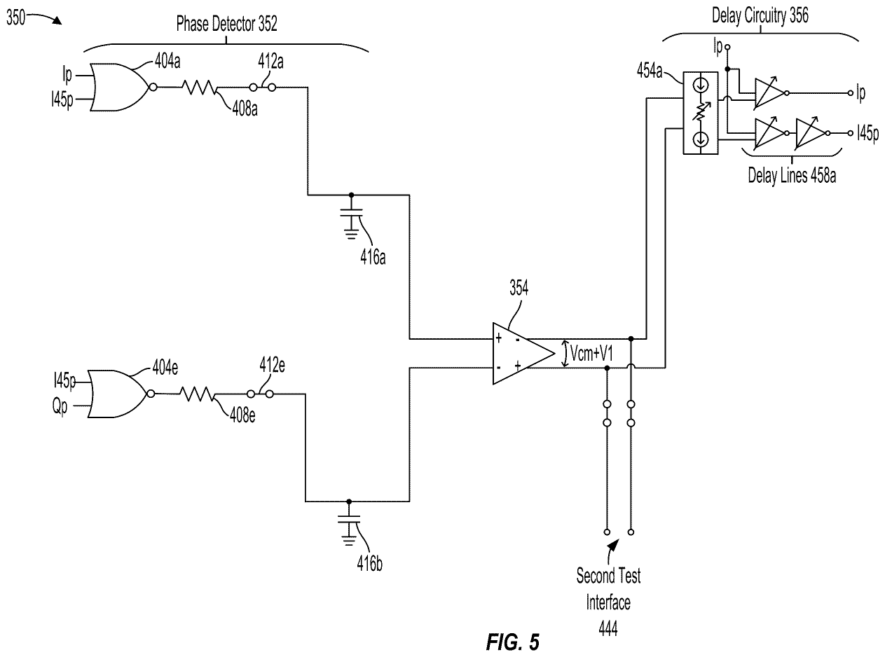

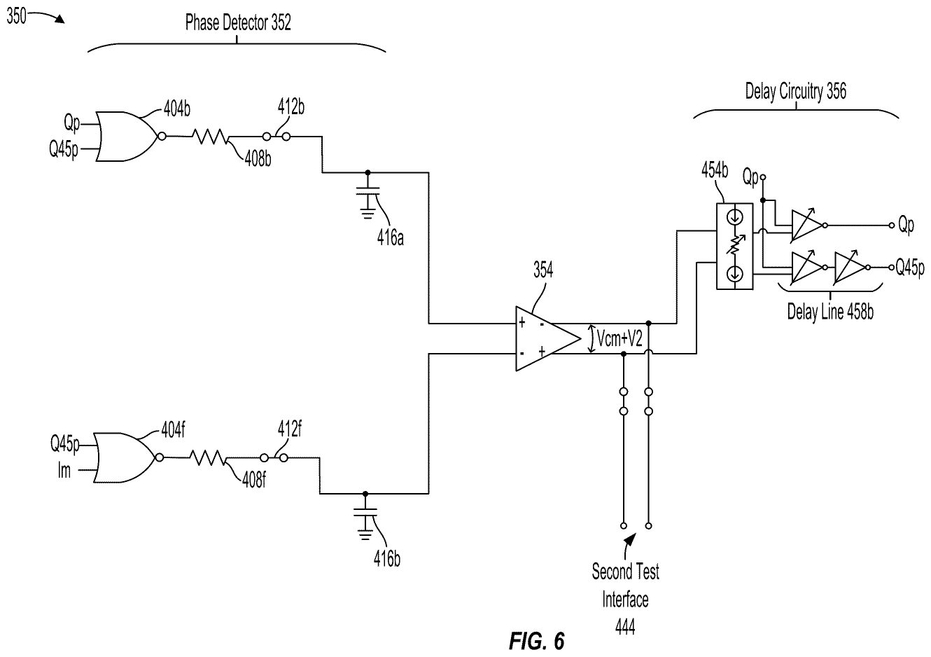

Controllers 240 and 280 may direct the operation at base station 105 and UE 115, respectively. Controller 240 or other processors and modules at base station 105 or controller 280 or other processors and modules at UE 115 may perform or direct the execution of various processes for the techniques described herein, such as to perform or direct the execution illustrated in FIG. 5 or FIG. 6, or other processes for the techniques described herein. Memories 242 and 282 may store data and program codes for base station 105 and UE 115, respectively. Scheduler 244 may schedule UEs for data transmission on the downlink or the uplink.

In some cases, UE 115 and base station 105 may operate in a shared radio frequency spectrum band, which may include licensed or unlicensed (e.g., contention-based) frequency spectrum. In an unlicensed frequency portion of the shared radio frequency spectrum band, UEs 115 or base stations 105 may traditionally perform a medium-sensing procedure to contend for access to the frequency spectrum. For example, UE 115 or base station 105 may perform a listen-before-talk or listen-before-transmitting (LBT) procedure such as a clear channel assessment (CCA) prior to communicating in order to determine whether the shared channel is available. In some implementations, a CCA may include an energy detection procedure to determine whether there are any other active transmissions. For example, a device may infer that a change in a received signal strength indicator (RSSI) of a power meter indicates that a channel is occupied. Specifically, signal power that is concentrated in a certain bandwidth and exceeds a predetermined noise floor may indicate another wireless transmitter. A CCA also may include detection of specific sequences that indicate use of the channel. For example, another device may transmit a specific preamble prior to transmitting a data sequence. In some cases, an LBT procedure may include a wireless node adjusting its own backoff window based on the amount of energy detected on a channel or the acknowledge/negative-acknowledge (ACK/NACK) feedback for its own transmitted packets as a proxy for collisions.

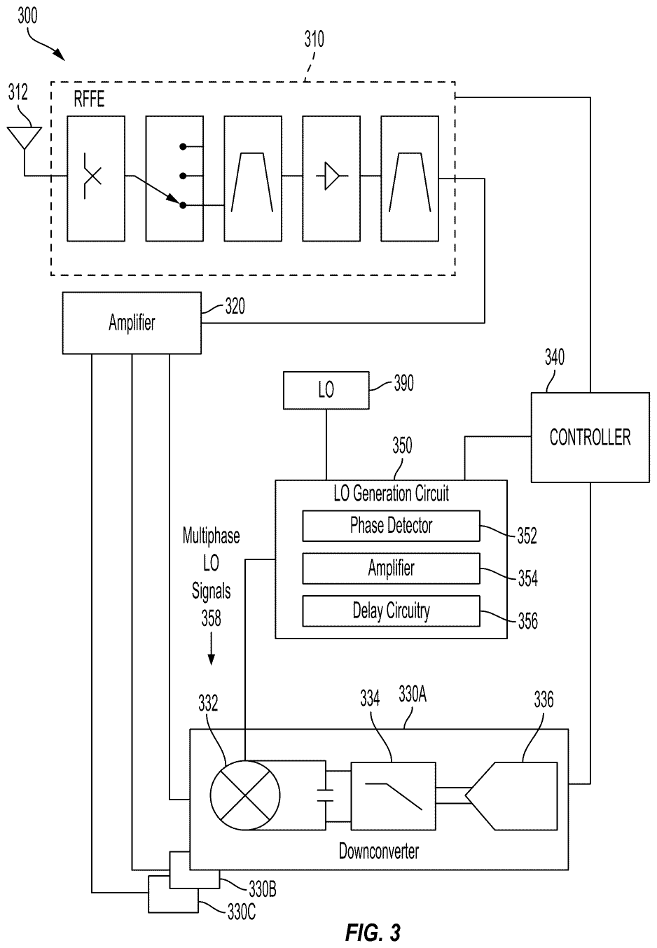

FIG. 3 is a block diagram illustrating a receiver circuit 300 that supports phase-adjustment of multiphase signals for an HRM. In some embodiments, the receiver circuit 300 may be part of a converged sub-6 Ghz and mmWave radio frequency (RF) transceiver, a sub-6 GHz radio frequency (RF) transceiver, or a mmWave radio frequency (RF) transceiver. In some embodiments, portions or all of the RF transceiver of FIG. 3 may be located in a single integrated circuit (IC) sharing a common substrate. The receiver circuit 300 may include an antenna 312 to receive radio frequency (RF) signals, such as a phase antenna array. The antenna 312 is coupled to a RF front-end (RFFE) 310, which may include duplexers, SAW filters, switches, LNAs, and/or other transmit or receive circuits for conditioning signals received from the antenna 312. In some embodiments, the RFFE 310 may include separate circuits for conditioning or otherwise processing sub-6 GHz signals, mmWave signals, satellite signals, and/or other signals. For example, the RFFE 310 may include a first plurality of circuits for conditioning a sub-6 GHz signal for further processing by other circuitry and a second plurality of circuits for conditioning a mmWave RF signal for further processing by other circuitry. The output of the RFFE 310 in this example may be an input RF signal to other circuitry comprising the conditioned sub-6 GHz signal and a conditioned mmWave IF signal. The RFFE 310 is coupled to an amplifier 320, such as a low noise amplifier (LNA). The amplifier 320 is coupled to one or more downconverters 330A, 330B, and 330C. Each of the downconverters 330A, 330B, and 330C may include mixers, such as a harmonic rejection mixer (HRM) 332, baseband filters (BBFs) 334, and/or analog-to-digital converters (ADCs) 336. The downconverters 330A, 330B, 330C may include one or more harmonic rejection mixers (HRMs). In some embodiments, the amplifier 320 is shared on an IC with one or more of the RFFE 310 and/or the downconverters 330A, 330B, and 330C.

Interference between wireless signals received at antenna 312 and processed through RFFE 310, amplifier 320, and downconverters 330A-C complicates operation of the receiver circuit 300, particularly when processing a large range of potential frequencies. For example, co-location of processing paths for sub-6 Ghz and mmWave signals in an integrated circuit can create interference between the sub-6 GHz signal harmonics and the mmWave signals. Interference between sub-6 GHz signals and mmWave signals may occur because mmWave IF signals corresponding to mmWave RF signals received at an antenna from over-the-air may be located near to sub-6 GHz signals in frequency (e.g., within 1-6 GHz) and/or located at harmonics of the sub-6 GHz (e.g., at integer multiples of the sub-6 GHz signals).

Interference between wireless signals may be further complicated by carrier aggregation (CA) operation. Carrier aggregation (CA) involves the combination of one or more carrier RF signals to carry a single data stream. Carrier aggregation (CA) improves the flexibility of the wireless devices and improves network utilization by allowing devices to be assigned different numbers of carriers for different periods of time based, at least in part, on historical, instantaneous, and/or predicted bandwidth use by the wireless device. Thus, when a mobile device needs additional bandwidth, additional carriers may be assigned to that wireless device, and then de-assigned and re-assigned to other mobile devices when bandwidth demands change. As carriers are assigned and de-assigned from a mobile device, the interaction of wireless signals may change. For example, different carriers in CA may be in different bands, and certain bands may have harmonics that overlap and/or otherwise interfere with certain other bands.

A controller 340 may detect conditions in the RF signal received from the antenna 312 or receive information regarding the carrier configuration from higher levels, such as a MAC layer or network layer. The controller 340 may configure components of the receiver circuit 300 to activate, deactivate, or control portions of the receiver circuit 300 to process an input RF signal. In some embodiments, the controller 340 configures components to reduce interference between bands within the receiver circuit 300. In some embodiments, the controller 340 may configure one or more processing paths of mixers within the downconverters 330A, 330B, and 330C.

In some aspects, the receiver circuit 300 may further include a local oscillator (LO) generation circuit. For example, the LO generation circuit may include or may correspond to configurable HRM control circuitry 350. The configurable HRM control circuitry 350 may be coupled to the controller 340 and to an HRM, such as the HRM 332. The configurable HRM control circuitry 350 may include a phase detector 352, an amplifier 354, and delay circuitry 356. The configurable HRM control circuitry 350 may provide multiphase local oscillator (LO) signals 358 to an HRM, such as the HRM 332. For example, in some implementations, the receiver circuit 300 may include or may be coupled to an LO 390. The LO 390 may provide the multiphase LO signals 358 to the configurable HRM control circuitry 350, and the configurable HRM control circuitry 350 may provide a phase-adjusted version of the multiphase LO signals 358 to the HRM 332.

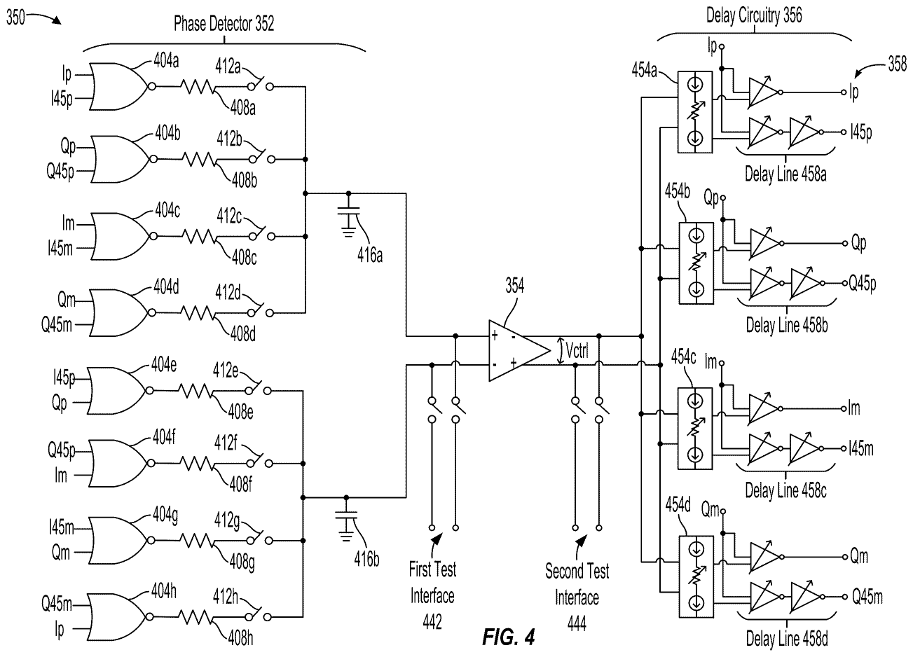

FIG. 4 is a diagram illustrating an example of configurable HRM control circuitry 350 that supports phase-adjustment of multiphase signals for an HRM. In some examples, the configurable HRM control circuitry 350 may be implemented in a transmitter. Alternatively, or in addition, the configurable HRM control circuitry 350 may be implemented in a receiver.

The configurable HRM control circuitry 350 may include a phase detector, such as the phase detector 352. The phase detector 352 may include not-or (NOR) gates 404a-h. The NOR gates 404a-h may be coupled to resistors 408a-h, respectively, and the resistors 408a-h may be coupled to a first set of switches, such as switches 412a-h, respectively. In some implementations, the phase detector 352 may include one or more capacitors. For example, the phase detector 352 may include a first capacitor 416a coupled to a first subset of the switches 412a-h and may further include a second capacitor 416b coupled to a second subset of the switches 412a-h. In some examples, the first subset may include the switches 412a-d, and the second subset may include the switches 412e-h.

The configurable HRM control circuitry 350 may further include one or more amplifiers, such as the amplifier 354. In some examples, the amplifier 354 may correspond to an operational amplifier (op amp), a differential amplifier, or both. In some implementations, the amplifier 354 may include a first input (e.g., a non-inverting input) coupled to the first capacitor 416a and to the switches 412a-d. The amplifier 354 may further include a second input (e.g., an inverting input) coupled to the second capacitor 416b and to the switches 412e-h. The amplifier 354 may further include a first output (e.g., an inverting output) and a second output (e.g., a non-inverting output).

In some implementations, the configurable HRM control circuitry 350 may include or may be coupled to one or more test interfaces. For example, an input of the amplifier 354 may be coupled to a first test interface 442. Alternatively, or in addition, an output of the amplifier 354 may be coupled to a second test interface 444. The first test interface 442 and the second test interface 444 may each include a set of switches configured to selectively enable or disable test operations. In such examples, the configurable HRM control circuitry 350 may include a second set of switches. The second set of switches may include switches coupled to the first input and the second input of amplifier 354, switches coupled to the first output and the second output of the amplifier 354, or both.

The configurable HRM control circuitry 350 may further include delay circuitry 356 coupled to the first output and the second output of the amplifier 354. In some examples, the delay circuitry 356 may include level shifters 454a-d. Each of the level shifters 454a-d may be coupled to outputs of the amplifier 354. For example, each of the level shifters 454a-d may be coupled to an inverting output of the amplifier 354 and may also be coupled to a non-inverting output of the amplifier 354. In some implementations, the level shifters 454a-d may correspond to direct current (DC) level shifters.

The delay circuitry 356 may further include delay lines coupled to the level shifters 454a-d. For example, the delay circuitry 356 may include delay lines 458a-d coupled to the level shifters 454a-d, respectively. Further, outputs of the delay lines 458a-d may be coupled to inputs of the NOR gates 404a-h. In some examples, the delay lines 458a-d may each include a delay locked loop (DLL) circuit.

During operation, the configurable HRM control circuitry 350 may perform phase-adjustment associated with one or more LO signals of the multiphase LO signals 358. In some examples, the multiphase LO signals 358 may be generated by a local oscillator (LO). In such examples, the NOR gates 404a-h may be coupled to the LO and may receive the multiphase LO signals 358 from the LO. In the example of FIG. 4, the multiphase LO signals 358 may include signals Ip, I45p, Qp, Q45p, Im, I45m, Qm, and Q45m. In some examples, the multiphase LO signals 358 may be phase separated from one another by 45 degrees or approximately 45 degrees. To illustrate, in some examples, the signals Ip, I45p, Qp, Q45p, Im, I45m, Qm, and Q45m may be associated with phases of 0 degrees, 45 degrees, 90 degrees, 135 degrees, 180 degrees, 225 degrees, 270 degrees, and 315 degrees, respectively.

In the example of FIG. 4, the NOR gate 404a may receive the signals Ip and I45p, and the NOR gate 404b may receive the signals Qp and Q45p. The NOR gate 404c may receive the signals Im and I45m, and the NOR gate 404d may receive the signals Qm and Q45m. The NOR gate 404e may receive the signals I45p and Qp, and the NOR gate 404f may receive the signals Q45p and Im. The NOR gate 404g may receive the signals I45m and Qm, and the NOR gate 404h may receive the signals Q45m and Ip.

Each of the NOR gates 404a-h may generate a respective output signal. To illustrate, the NOR gate 404a may generate an output signal based on the signals Ip and I45p. In an example, the output signal of the NOR gate 404a may have a logic one value if both the signals Ip and I45p have logic zero values. If one or both of the signals Ip and I45p have a logic one value, the output signal of the NOR gate 404a may have a logic zero value. Further, the other NOR gates 404b-h may also generate respectively output signals based on values of the signals input to the NOR gates 404b-h.

The switches 412a-h may be activated or deactivated to selectively couple the NOR gates 404a-h to the delay circuitry 356. In some implementations, control signals may be provided to the switches 412a-h to activate or deactivate each of the switches 412a-h to enable phase-adjustment of one or more of the multiphase LO signals 358. Some further examples are described further with reference to FIGS. 5-8.

The amplifier 354 may receive output signals of at least some of the NOR gates 404a-h based on which of the switches 412a-h are activated. The amplifier 354 may generate a signal based on the received output signals. For example, the signal may correspond to a voltage Vctrl.

In some examples, one or more of the first test interface 442 or the second test interface 444 may enable measurement of the voltage Vctrl. Further, based on the measurement, one or more of the multiphase LO signals 358 may be phase-adjusted. To further illustrate, some additional examples are described further with reference to FIGS. 5-8.

FIG. 5 is a diagram illustrating an example of a first configurable state of the configurable HRM control circuitry 350 that supports phase-adjustment of multiphase signals for an HRM. In the example of FIG. 5, some components may be illustrated while other components may be omitted for clarity. For example, the switches 412a and 412e may be activated to couple the NOR gates 404a and 404e to the amplifier 354, while the switches 412b-d and 412f-h may be deactivated to uncouple the NOR gates 404b-d and 404f-h from the amplifier 354.

The NOR gate 404a may receive the signals Ip and I45p and may generate an output signal based on the signals Ip and I45p. The NOR gate 404e may receive the signals I45p and Qp and may generate an output signal based on the signals I45p and Qp.

The amplifier 354 may receive the output signals of the NOR gates 404a and 404e. Based on the output signals, the amplifier 354 may generate a signal, such as a voltage Vcm+V1, where V1 may represent a phase error associated with the signal I45p. For example, a target phase of the signal I45p may correspond to 45 degrees, and a magnitude of V1 may indicate a difference between the actual phase of the signal I45p and the target phase.

One or more test interfaces may enable measurement of the signal output by the amplifier 354. In the example of FIG. 5, the second test interface 444 may be used to measure the signal output by the amplifier 354 (e.g., by activating switches of the second test interface 444) and the first test interface 442 may be deactivated (e.g., by deactivating switches of the first test interface 442). Further, in some implementations, test equipment may be coupled to one or both of the first test interface 442 or the second test interface 444 to perform one or more operations described herein, such as phase-adjustment of one or more of the multiphase LO signals 358.

To illustrate, based on the output signal of the amplifier 354, the delay line 458a may modify a phase of the signal I45p. For example, a control signal provided to the level shifter 454a may be modified to adjust a bias voltage associated with the delay line 458a in order to phase-adjust the signal I45p. In some implementations, after adjusting the bias voltage to phase-adjust the signal I45p, the output signal of the amplifier 354 may be remeasured, and one or more additional phase-adjustments of the signal I45p may be performed (e.g., to decrease the voltage V1 to below a threshold voltage or to achieve a target phase of the signal I45p).

FIG. 6 is a diagram illustrating an example of a second configurable state of the configurable HRM control circuitry 350 that supports phase-adjustment of multiphase signals for an HRM. In the example of FIG. 6, some components may be illustrated while other components may be omitted for clarity. For example, the switches 412b and 412f may be activated to couple the NOR gates 404b and 404f to the amplifier 354, while the switches 412a, 412c-e, and 412g-h may be deactivated to uncouple the NOR gates 404a, 404c-e, and 404g-h from the amplifier 354.

The NOR gate 404b may receive the signals Qp and Q45p and may generate an output signal based on the signals Qp and Q45p. The NOR gate 404f may receive the signals Q45p and Im and may generate an output signal based on the signals Q45p and Im.

The amplifier 354 may receive the output signals of the NOR gates 404b and 404f. Based on the output signals, the amplifier 354 may generate a signal, such as a voltage Vcm+V2, where V2 may represent a phase error associated with the signal Q45p. For example, a target phase of the signal Q45p may correspond to 135 degrees, and a magnitude of V2 may indicate a difference between the actual phase of the signal Q45p and the target phase.

One or more test interfaces may enable measurement of the signal output by the amplifier 354. In the example of FIG. 6, the second test interface 444 may be used to measure the signal output by the amplifier 354 (e.g., by activating switches of the second test interface 444) and the first test interface 442 may be deactivated (e.g., by deactivating switches of the first test interface 442). Further, in some implementations, test equipment may be coupled to one or both of the first test interface 442 or the second test interface 444 to perform one or more operations described herein, such as phase-adjustment of one or more of the multiphase LO signals 358.

To illustrate, based on the output signal of the amplifier 354, the delay line 458b may modify a phase of the signal Q45p. For example, a control signal provided to the level shifter 454b may be modified to adjust a bias voltage associated with the delay line 458b in order to phase-adjust the signal Q45p. In some implementations, after adjusting the bias voltage to phase-adjust the signal Q45p, the output signal of the amplifier 354 may be remeasured, and one or more additional phase-adjustments of the signal Q45p may be performed (e.g., to decrease the voltage V2 to below a threshold voltage or to achieve a target phase of the signal Q45p).

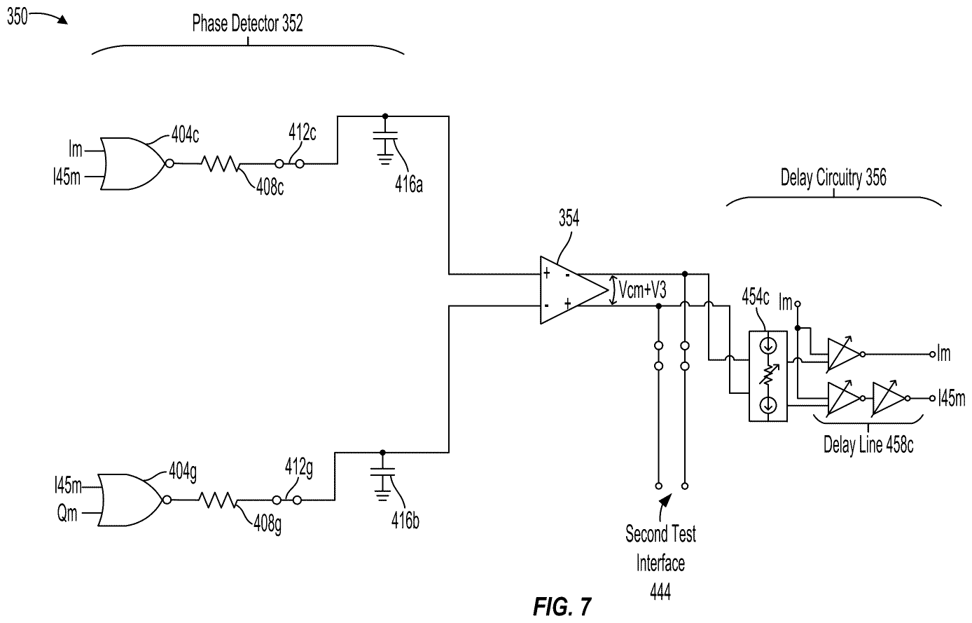

FIG. 7 is a diagram illustrating an example of a third configurable state of the configurable HRM control circuitry 350 that supports phase-adjustment of multiphase signals for an HRM. In the example of FIG. 7, some components may be illustrated while other components may be omitted for clarity. For example, the switches 412c and 412g may be activated to couple the NOR gates 404c and 404g to the amplifier 354, while the switches 412a-b, 412d-f, and 412h may be deactivated to uncouple the NOR gates 404a-b, 404d-f, and 404h from the amplifier 354.

The NOR gate 404c may receive the signals Im and I45m and may generate an output signal based on the signals Im and I45m. The NOR gate 404g may receive the signals I45m and Qm and may generate an output signal based on the signals I45m and Qm.

The amplifier 354 may receive the output signals of the NOR gates 404c and 404g. Based on the output signals, the amplifier 354 may generate a signal, such as a voltage Vcm+V3, where V3 may represent a phase error associated with the signal I45m. For example, a target phase of the signal I45m may correspond to 225 degrees, and a magnitude of V3 may indicate a difference between the actual phase of the signal I45m and the target phase.

One or more test interfaces may enable measurement of the signal output by the amplifier 354. In the example of FIG. 7, the second test interface 444 may be used to measure the signal output by the amplifier 354 (e.g., by activating switches of the second test interface 444) and the first test interface 442 may be deactivated (e.g., by deactivating switches of the first test interface 442). Further, in some implementations, test equipment may be coupled to one or both of the first test interface 442 or the second test interface 444 to perform one or more operations described herein, such as phase-adjustment of one or more of the multiphase LO signals 358.

To illustrate, based on the output signal of the amplifier 354, the delay line 458c may modify a phase of the signal I45m. For example, a control signal provided to the level shifter 454c may be modified to adjust a bias voltage associated with the delay line 458c in order to phase-adjust the signal I45m. In some implementations, after adjusting the bias voltage to phase-adjust the signal I45m, the output signal of the amplifier 354 may be remeasured, and one or more additional phase-adjustments of the signal I45m may be performed (e.g., to decrease the voltage V3 to below a threshold voltage or to achieve a target phase of the signal I45m).

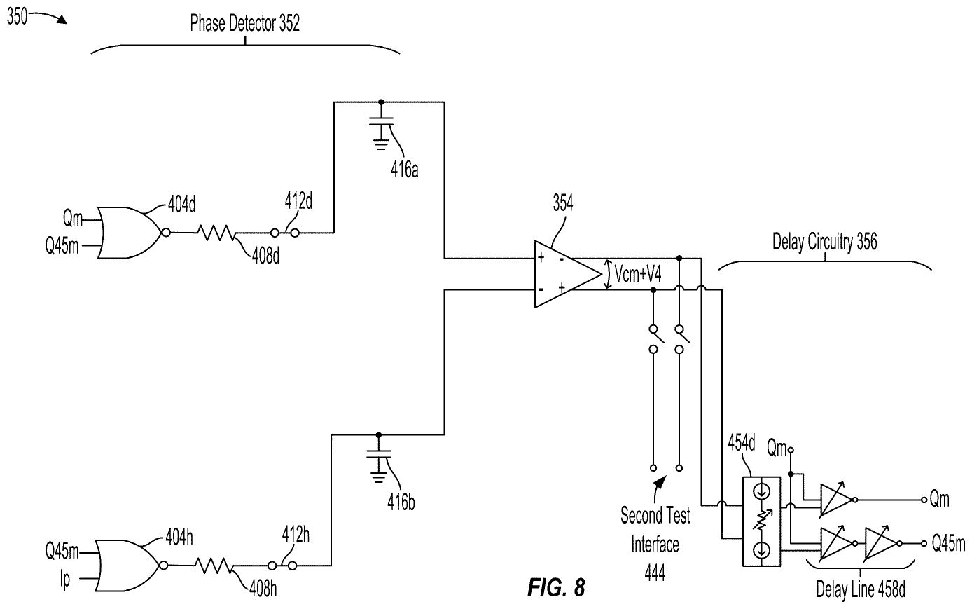

FIG. 8 is a diagram illustrating an example of a fourth configurable state of the configurable HRM control circuitry 350 that supports phase-adjustment of multiphase signals for an HRM. In the example of FIG. 8, some components may be illustrated while other components may be omitted for clarity. For example, the switches 412d and 412h may be activated to couple the NOR gates 404d and 404h to the amplifier 354, while the switches 412a-c and 412e-g may be deactivated to uncouple the NOR gates 404a-c and 404e-g from the amplifier 354.

The NOR gate 404d may receive the signals Qm and Q45m and may generate an output signal based on the signals Qm and Q45m. The NOR gate 404h may receive the signals Q45m and Ip and may generate an output signal based on the signals Q45m and Ip.

The amplifier 354 may receive the output signals of the NOR gates 404d and 404h. Based on the output signals, the amplifier 354 may generate a signal, such as a voltage Vcm+V4, where V4 may represent a phase error associated with the signal Q45m. For example, a target phase of the signal Q45m may correspond to 315 degrees, and a magnitude of V4 may indicate a difference between the actual phase of the signal Q45m and the target phase.

One or more test interfaces may enable measurement of the signal output by the amplifier 354. In the example of FIG. 8, the second test interface 444 may be used to measure the signal output by the amplifier 354 (e.g., by activating switches of the second test interface 444) and the first test interface 442 may be deactivated (e.g., by deactivating switches of the first test interface 442). Further, in some implementations, test equipment may be coupled to one or both of the first test interface 442 or the second test interface 444 to perform one or more operations described herein, such as phase-adjustment of one or more of the multiphase LO signals 358.

To illustrate, based on the output signal of the amplifier 354, the delay line 458d may modify a phase of the signal Q45m. For example, a control signal provided to the level shifter 454d may be modified to adjust a bias voltage associated with the delay line 458d in order to phase-adjust the signal Q45m. In some implementations, after adjusting the bias voltage to phase-adjust the signal Q45m, the output signal of the amplifier 354 may be remeasured, and one or more additional phase-adjustments of the signal Q45m may be performed (e.g., to decrease the voltage V4 to below a threshold voltage or to achieve a target phase of the signal Q45m).

The examples of FIGS. 5-8 illustrate that different subsets of components may be selectively activated and deactivated to facilitate individual phase-adjustment of the multiphase LO signals 358. For example, in FIG. 5, the switches 412a and 412e may be activated to selectively couple the NOR gates 404a and 404e to the delay circuitry 356. As another example, in FIG. 6, the switches 412b and 412f may be activated to selectively couple the NOR gates 404b and 404f to the delay circuitry 356. In FIG. 7, the switches 412c and 412g may be activated to selectively couple the NOR gates 404c and 404g to the delay circuitry 356. In FIG. 8, the switches 412d and 412h may be activated to selectively couple the NOR gates 404d and 404h to the delay circuitry 356.

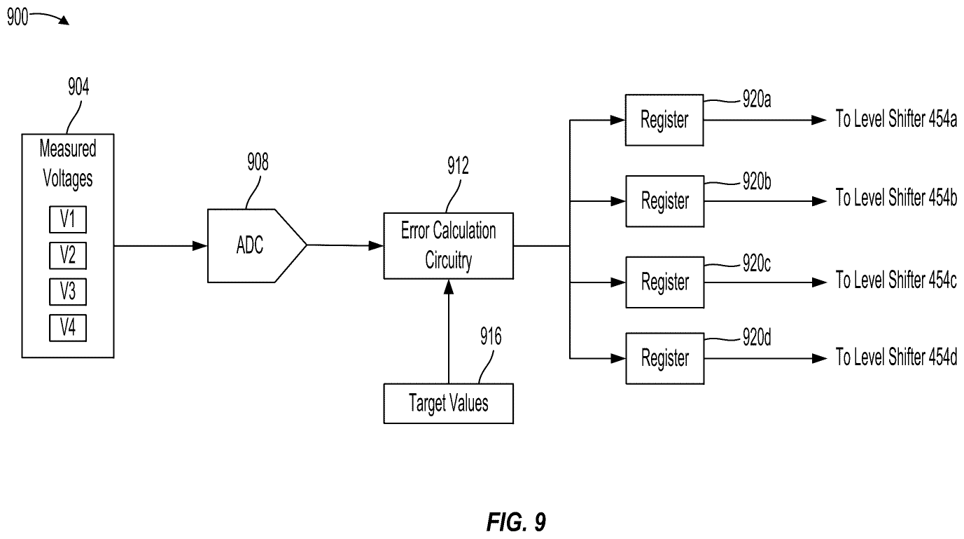

FIG. 9 is a block diagram illustrating an example of a calibration subsystem 900 that supports phase-adjustment of multiphase signals for an HRM. In some examples, features of the calibration subsystem may be included in one or more devices described herein, such as a UE 115, a base station 105, the receiver circuit 300, or one or more other devices. Further, in some examples, the calibration subsystem 900 may be coupled to the configurable HRM control circuitry 350.

The calibration subsystem 900 may include one or more analog-to-digital converters (ADCs), such as an ADC 908. In some examples, an input of the ADC 908 may be coupled to the first test interface 442, to the second test interface 444, or both.

The calibration subsystem 900 may further include error calculation circuitry 912. The error calculation circuitry 912 may be coupled to an output of the ADC 908. In some implementations, the error calculation circuitry 912 may include one or more comparator circuits.

The calibration subsystem 900 may further include registers 920a, 920b, 920c, and 920d. The registers 920a-d may be coupled to an output of the error calculation circuitry 912. In some examples, the registers 920a-d may be coupled to the level shifters 454a-d, respectively.

During operation, the ADC 908 may receive measured voltages 904 associated with calibration of the HRM 332. For example, the ADC 908 may receive the voltages V1 of FIG. 5, V2 of FIG. 6, V3 of FIG. 7, and V4 of FIG. 8 during different respective calibration phases associated with the HRM 332. The ADC 908 may digitize the measured voltages 904 to generate digital values and may provide the digital values to the error calculation circuitry 912.

The error calculation circuitry 912 may receive the digital values. The error calculation circuitry 912 may compare each of the digital values to a respective target value of target values 916. Based on differences between the digital values and the target values 916, the error calculation circuitry 912 may determine bias values and may store indications of the bias values to the registers 920a-d. The bias values may be used to adjust operation of the level shifters 454a-d, such as by adjusting bias voltages applied to the level shifters 454a-d.

As an illustrative example, the error calculation circuitry 912 may determine a difference between V1 and a corresponding target value of the target values 916. Based on the difference, the error calculation circuitry 912 may determine a bias value to be applied to the level shifter 454a to cancel or reduce V1. The error calculation circuitry 912 may store an indication of the bias value to the register 920a.

After calibration, each of the switches 412a-h may be activated (e.g., closed) to couple the NOR gates 404a-h to the amplifier 354 (e.g., in connection with a mission mode of operation). A verification process may be performed, which may include measuring an average phase error associated with the and confirming that the average phase error of the multiphase LO signals 358 is less than a threshold phase error. Further, the verification process may include determining that Vctrl of FIG. 4 is less than a threshold voltage.

Further, the multiphase LO signals 358 may be provided to an HRM, such as the HRM 332, to reduce harmonic distortion or other undesired signal components in connection with receive operations, transmit operations, or both (e.g., after completion of calibration and verification and during a “mission” mode of operation). To illustrate, after determining settings of the delay circuitry 356 (e.g., bias signals provided to level shifters 454a-d), the settings may be stored to a memory (e.g., a nonvolatile memory). Upon device powerup, the delay circuitry 356 may be operated in accordance with the settings (e.g., by providing the bias values from the memory to the registers 920a-d, and by providing the bias signals to the level shifters 454a-d based on the bias values such that phase errors of the multiphase LO signals 358 are canceled or reduced).

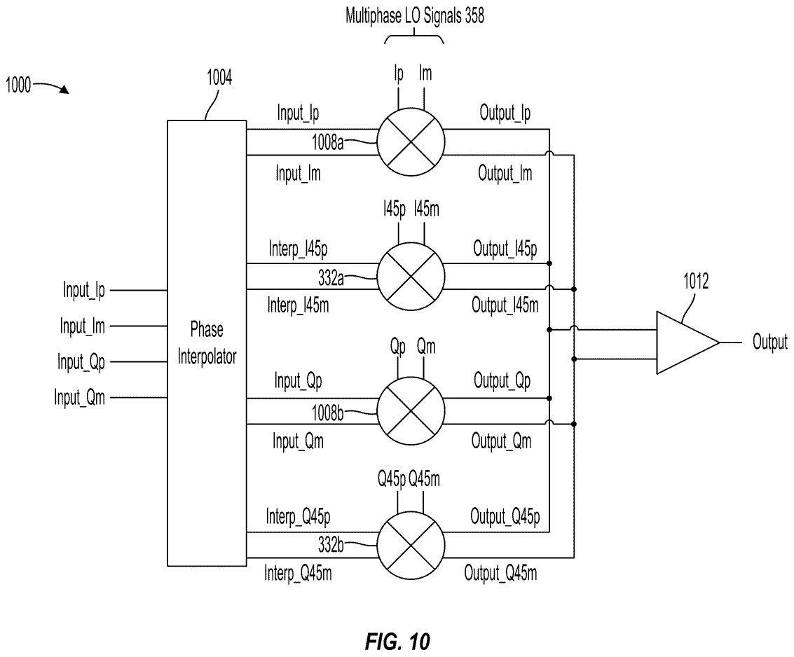

FIG. 10 is a diagram illustrating an example of a mixer stage 1000 that supports phase-adjustment of multiphase signals for an HRM. In some examples, the mixer stage 1000 may be included in one or more devices described herein, such as the UE 115, the base station 105, the receiver circuit 300, or a transmit circuit. The mixer stage 1000 may be coupled to the configurable HRM control circuitry 350.

The mixer stage 1000 may include a phase interpolator 1004, such as a passive voltage-mode phase interpolator. The phase interpolator 1004 may be coupled to a primary mixer, which may include mixers 1008a and 1008b, and to an auxiliary mixer, which may include HRMs 332a and 332b. The mixers 1008a-b and the HRMs 332a-b may be coupled to a circuit 1012 (e.g., one or more of an amplifier or a summation circuit).

During operation, the phase interpolator 1004 may receive a signal, such as a transmit signal or a receive signal. The signal may include signal components input_Ip, input_Im, input_Qp, and input_Qm, which may correspond to a positive in-phase signal component, a negative in-phase signal component, a positive quadrature signal component, and a negative quadrature signal component, respectively. The phase interpolator 1004 may perform phase interpolation of the signal to generate signal components interp_I45p, interp_I45m, interp_Q45p, and interp_Q45m. The phase interpolator 1004 may output the signal components input_Ip, input_Im, input_Qp, input_Qm, interp_I45p, interp_I45m, interp_Q45p, and interp_Q45m to the mixers 1008a-b and the HRMs 332a-b.

The mixers 1008a-b and the HRMs 332a-b may receive the signal components and the multiphase LO signals 358. The mixers 1008a-b and the HRMs 332a-b may perform cancelation or reduction of harmonic content associated with the signal components to generate output signal components, such as output_Ip, output_Im, output_Qp, output_Qm, output_I45p, output_I45m, output_Q45p, and output_Q45m. The output signal components may have increased gain and reduced harmonic content as compared to the input signal components. For example, the output signal components may add in phase for a fundamental signal component, increasing gain. Further, the output signal components may add out of phase for some other signal components, such as for third and fifth LO harmonic components, resulting in reduction or cancelation of harmonic content.

The circuit 1012 may receive the output signal components and may generate an output (e.g., a single-ended output) based on the output signal components.

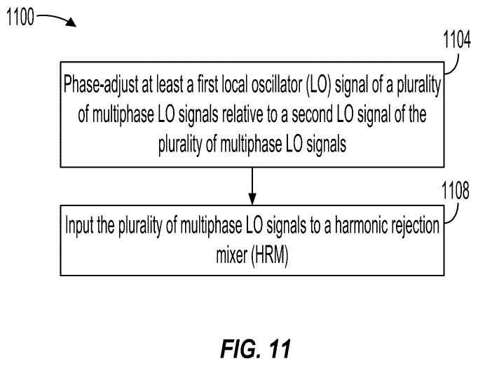

FIG. 11 is a flow chart illustrating an example of a method 1100 of operation of a device that supports phase-adjustment of multiphase signals for an HRM. In some examples, the device may include or may correspond to the UE 115, the base station 105, the receiver circuit 300, a transmit circuit, the configurable HRM control circuitry 350, or the mixer stage 1000. Further, although some examples may be described with reference to receive operations for illustration, in other examples, one or more operations herein may be performed in connection with transmit operations (e.g., to adjust operation of an HRM of a transmitter). In such examples, the device described with reference to FIG. 11 may correspond to a transmitter.

The method 1100 includes phase-adjusting at least a first local oscillator (LO) signal of a plurality of multiphase LO signals relative to a second LO signal of the plurality of multiphase LO signals, at 1104. In some examples, the first LO signal may include one of the multiphase LO signals 358, such as one of the signals I45p, Q45p, I45m, or Q45m. In some examples, the second LO signal may correspond to another one of the multiphase LO signals 358, such as one of the signals Ip, Qp, Im, or Qm.

The method 1100 further includes inputting the plurality of multiphase LO signals to a harmonic rejection mixer (HRM), at 1108. For example, the configurable HRM control circuitry 350 may provide the multiphase LO signals 358 to the HRM 332 or to another HRM.

In some examples, the method 1100 may further include performing one or more operations using the HRM and in accordance with the multiphase LO signals 358. For example, based on the multiphase LO signals 358 provided to the HRM 332, the receiver circuit 300 may perform a receive operation to receive and process one or more wireless signals. In some other examples, the one or more operations may include a transmit operation to process and transmit one or more wireless signals.

To further illustrate, although some examples may be described with reference to a receiver (such as the receiver circuit 300), other examples are also within the scope of the disclosure. For example, the configurable HRM control circuitry 350 may be included in a transmitter (or transceiver) and may calibrate operation associated with an HRM of the transmitter (or transceiver). Accordingly, one or more features described herein may be used in connection with processing of a received signal, a transmit signal, or both.

Further, although some examples may be described with reference to eight multiphase LO signals (Ip, I45p, Qp, Q45p, Im, I45m, Qm, and Q45m), other examples are also within the scope of the disclosure. For example, in some implementations, a single-ended implementation may use four such multiphase LO signals instead of eight multiphase LO signals. Other examples are also within the scope of the disclosure.

One or more features described herein may improve performance of a wireless device (such as a wireless transmitter, a wireless receiver, or both) while also reducing cost, size, and power consumption of the wireless device. For example, in some implementations, LO signals provided to an HRM (such as the HRM 332) may be phase adjusted using relatively simple direct current (DC) signals provided to DC level shifters and without increasing size of transistors of the HRM. As a result, device cost, size, and power consumption may be reduced as compared to some other conventional devices, such as devices that increase the size of transistors of an HRM to reduce (or “hide”) effects of a phase mismatch.

In a first aspect, an apparatus includes a multiphase harmonic rejection mixer (HRM) configured to receive a plurality of multiphase local oscillator (LO) signals. The apparatus further includes delay circuitry coupled to the multiphase HRM. The delay circuitry is configured to phase-adjust at least a first LO signal of the plurality of multiphase LO signals relative to a second LO signal of the plurality of multiphase LO signals.

In a second aspect, in combination with the first aspect, the delay circuitry includes a delay line configured to output the first LO signal and the second LO signal. The delay circuitry further includes a level shifter coupled to the delay line. The level shifter is configured to set a bias voltage provided to the delay line to phase-adjust the first LO signal relative to the second LO signal.

In a third aspect, in combination with one or more of the first aspect or the second aspect, the apparatus further includes a register coupled to the level shifter. The register is configured to store a bias value associated with phase-adjustment of the first LO signal.

In a fourth aspect, in combination with one or more of the first aspect through the third aspect, the register is configured to set the bias voltage of the level shifter in accordance with the bias value.

In a fifth aspect, in combination with one or more of the first aspect through the fourth aspect, the apparatus further includes a phase detector coupled to the delay circuitry. The phase detector includes multiple not-or (NOR) gates configured to receive the plurality of multiphase LO signals.

In a sixth aspect, in combination with one or more of the first aspect through the fifth aspect, the phase detector further includes multiple switches coupled to the multiple NOR gates. The multiple switches are configured to selectively couple a subset of the multiple NOR gates to the delay circuitry to enable phase-adjustment of the first LO signal.

In a seventh aspect, in combination with one or more of the first aspect through the sixth aspect, the apparatus further includes an amplifier coupled to the delay circuitry. The amplifier is configured to output a signal indicating a phase error associated with the first LO signal and the second LO signal.

In an eighth aspect, in combination with one or more of the first aspect through the seventh aspect, the apparatus further includes a test interface coupled to the amplifier. The test interface is configured to enable measurement of the signal.

In a ninth aspect, in combination with one or more of the first aspect through the eighth aspect, the test interface is coupled to an output of the amplifier.

In a tenth aspect, in combination with one or more of the first aspect through the ninth aspect, the test interface is coupled to an input of the amplifier.

In an eleventh aspect, a method includes phase-adjusting at least a first local oscillator (LO) signal of a plurality of multiphase LO signals relative to a second LO signal of the plurality of multiphase LO signals. The method further includes inputting the plurality of multiphase LO signals to a harmonic rejection mixer (HRM).

In a twelfth aspect, in combination with the eleventh aspect, the method further includes setting, using a level shifter, a bias voltage provided to a delay line to enable the delay line to phase-adjust the first LO signal relative to the second LO signal.

In a thirteenth aspect, in combination with one or more of the eleventh aspect through the twelfth aspect, the method further includes outputting the first LO signal and the second LO signal from the delay line in accordance with the bias voltage.

In a fourteenth aspect, in combination with one or more of the eleventh aspect through the thirteenth aspect, the method further includes outputting, from a register associated to the level shifter, a bias value associated with phase-adjustment of the first LO signal.

In a fifteenth aspect, in combination with one or more of the eleventh aspect through the fourteenth aspect, the bias voltage of the level shifter is set in accordance with the bias value.

In a sixteenth aspect, an apparatus includes means for phase-adjusting at least a first local oscillator (LO) signal of a plurality of multiphase LO signals relative to a second LO signal of the plurality of multiphase LO signals. The apparatus further includes means for performing harmonic rejection mixing (HRM) in accordance with the plurality of multiphase LO signals.

In a seventeenth aspect, in combination with the sixteenth aspect, the apparatus further includes means for setting a bias voltage provided to means for phase-adjusting to enable the means for phase-adjusting to phase-adjust the first LO signal relative to the second LO signal.

In an eighteenth aspect, in combination with one or more of the sixteenth aspect through the seventeenth aspect, the means for phase-adjusting is configured to output the first LO signal and the second LO signal in accordance with the bias voltage.

In a nineteenth aspect, in combination with one or more of the sixteenth aspect through the eighteenth aspect, the apparatus further includes means for storing a bias value associated with phase-adjustment of the first LO signal.

In a twentieth aspect, in combination with one or more of the sixteenth aspect through the nineteenth aspect, the means for phase-adjusting the first LO signal is configured to set the bias voltage in accordance with the bias value.

In a twenty-first aspect, an apparatus includes a harmonic rejection mixer (HRM) and a local oscillator (LO) generation circuit coupled to the HRM. The LO generation circuit includes a phase detector comprising multiple paths and a first set of switches. The first set of switches includes a respective switch in each path of the multiple paths. The LO generation circuit further includes an amplifier coupled to the phase detector and a second set of switches coupled to at least one of an input of the amplifier or an output of the amplifier. The LO generation circuit further includes a plurality of direct current (DC) level shifters coupled to the amplifier and a plurality of delay lines coupled to the plurality of DC level shifters.

In a twenty-second aspect, in combination with the twenty-first aspect, each path of the multiple paths further includes a not-or (NOR) gate and a resistor coupled to the NOR gate.

In a twenty-third aspect, in combination with one or more of the twenty-first aspect through the twenty-second aspect, the amplifier is a differential amplifier, the input of the amplifier includes a first input and a second input, and the second set of switches includes a respective switch coupled to each of the first input and the second input.

In a twenty-fourth aspect, in combination with one or more of the twenty-first aspect through the twenty-third aspect, the amplifier is a differential amplifier, the output of the amplifier includes a first output and a second output, and the second set of switches includes a respective switch coupled to each of the first output and the second output.

In a twenty-fifth aspect, in combination with one or more of the twenty-first aspect through the twenty-fourth aspect, the amplifier is a differential amplifier, the input of the amplifier includes a first input and a second input, the output of the amplifier includes a first output and a second output, and the second set of switches includes a respective switch coupled to each of the first input, the second input, the first output, and the second output.

In the figures, a single block may be described as performing a function or functions: The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including components such as a processor, memory, and the like.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or process disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and “back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus comprising:
a multiphase harmonic rejection mixer (HRM) configured to receive a plurality of multiphase local oscillator (LO) signals; and
delay circuitry coupled to the multiphase HRM, the delay circuitry configured to phase-adjust at least a first LO signal of the plurality of multiphase LO signals relative to a second LO signal of the plurality of multiphase LO signals.

2. The apparatus of claim 1, wherein the delay circuitry includes:
a delay line configured to output the first LO signal and the second LO signal; and
a level shifter coupled to the delay line, the level shifter configured to set a bias voltage provided to the delay line to phase-adjust the first LO signal relative to the second LO signal.

3. The apparatus of claim 2, further comprising a register coupled to the level shifter, the register configured to store a bias value associated with phase-adjustment of the first LO signal.

4. The apparatus of claim 3, wherein the register is configured to set the bias voltage of the level shifter in accordance with the bias value.

5. The apparatus of claim 1, further comprising a phase detector coupled to the delay circuitry, wherein the phase detector includes multiple not-or (NOR) gates configured to receive the plurality of multiphase LO signals.

6. The apparatus of claim 5, wherein the phase detector further includes multiple switches coupled to the multiple NOR gates, and wherein the multiple switches are configured to selectively couple a subset of the multiple NOR gates to the delay circuitry to enable phase-adjustment of the first LO signal.

7. The apparatus of claim 1, further comprising an amplifier coupled to the delay circuitry, wherein the amplifier is configured to output a signal indicating a phase error associated with the first LO signal and the second LO signal.

8. The apparatus of claim 7, further comprising a test interface coupled to the amplifier, wherein the test interface is configured to enable measurement of the signal.

9. The apparatus of claim 8, wherein the test interface is coupled to an output of the amplifier.

10. The apparatus of claim 8, wherein the test interface is coupled to an input of the amplifier.

11. A method comprising:
phase-adjusting at least a first local oscillator (LO) signal of a plurality of multiphase LO signals relative to a second LO signal of the plurality of multiphase LO signals; and
inputting the plurality of multiphase LO signals to a harmonic rejection mixer (HRM).

12. The method of claim 11, further comprising setting, using a level shifter, a bias voltage provided to a delay line to enable the delay line to phase-adjust the first LO signal relative to the second LO signal.

13. The method of claim 12, further comprising outputting the first LO signal and the second LO signal from the delay line in accordance with the bias voltage.

14. The method of claim 12, further comprising outputting, from a register associated to the level shifter, a bias value associated with phase-adjustment of the first LO signal.

15. The method of claim 14, wherein the bias voltage of the level shifter is set in accordance with the bias value.

16. An apparatus comprising:
a harmonic rejection mixer (HRM); and
a local oscillator (LO) generation circuit coupled to the HRM and comprising:
a phase detector comprising multiple paths and a first set of switches, the first set of switches including a respective switch in each path of the multiple paths;
an amplifier coupled to the phase detector;
a second set of switches coupled to at least one of an input of the amplifier or an output of the amplifier;
a plurality of direct current (DC) level shifters coupled to the amplifier; and
a plurality of delay lines coupled to the plurality of DC level shifters.

17. The apparatus of claim 16, wherein each path of the multiple paths further includes a not-or (NOR) gate and a resistor coupled to the NOR gate.

18. The apparatus of claim 16, wherein the amplifier is a differential amplifier, wherein the input of the amplifier includes a first input and a second input, and wherein the second set of switches includes a respective switch coupled to each of the first input and the second input.

19. The apparatus of claim 16, wherein the amplifier is a differential amplifier, wherein the output of the amplifier includes a first output and a second output, and wherein the second set of switches includes a respective switch coupled to each of the first output and the second output.

20. The apparatus of claim 16, wherein the amplifier is a differential amplifier, wherein the input of the amplifier includes a first input and a second input, wherein the output of the amplifier includes a first output and a second output, and wherein the second set of switches includes a respective switch coupled to each of the first input, the second input, the first output, and the second output.
